(19) United States
(12) Patent Application Publication
(10) Pub. No.: US 2026/0130292 A1
(43) Pub. Date: May 7, 2026

(54) INTEGRATED CIRCUIT (IC) PACKAGE HAVING A PACKAGE INTERCONNECT INCLUDING A PILLAR AND A SOLDER CAP COUPLED TO A BOTTOM SURFACE OF THE PILLAR TO REDUCE THE HEIGHT OF THE IC PACKAGE

(71) Applicant: QUALCOMM Incorporated, San Diego, CA (US)

(72) Inventors: Kyudong Kang, Seoul (KR); Heun Gun Shin, San Diego, CA (US); Choi Myungryul, Paju (KR); Yongsuk Lee, Seoul (KR)

(21) Appl. No.: 18/936,258

(22) Filed: Nov. 4, 2024

(51) Int. Cl. H01L 23/498; H01L 23/31; H01L 23/538; H01L 25/00; H01L 25/10

(52) U.S. Cl. CPC H10W 90/701; H10W 70/611; H10W 70/685; H10W 90/00; H10W 70/60; H10W 74/111

(57) ABSTRACT

An electronic device including an IC having a package interconnect including a pillar and a solder cap coupled to a bottom surface of the pillar to reduce the height of the IC package. The IC package includes a substrate comprising an outer metallization layer having a metal pad and a package mold layer adjacent to the outer metallization layer. The pillar has a top surface and a bottom surface. The pillar extends through the package mold layer with the top surface coupled to the metal pad and the bottom surface coupled to the solder cap. In contrast to conventional package interconnects, such as ball grid arrays (BGA), for example, deploying the solder cap on the bottom surface of the pillar advantageously results in using less solder and tighter pitch between adjacent package interconnects because the width of the pillar is less than a solder ball in a BGA.

### TECHNICAL FIELD

The field of the disclosure relates to integrated circuit (IC) packages, and more particularly to design and manufacturing of package interconnects.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The die(s) is electrically interfaced to metal interconnects (e.g., metal traces) exposed in a top layer of the package substrate. The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes a bottom, outer metallization layer that includes metal interconnects coupled to external metal interconnects (e.g., ball grid array (BGA) interconnects, land grid array (LGA)) to provide an external interface between the die(s) in the IC package. The external metal interconnects can also be coupled (e.g., soldered) to traces in a printed circuit board (PCB) to attach the package to the PCB and interface its die(s) with the circuitry of the PCB. The die(s) may be mounted to the top layer of the package substrate through die interconnects. Other die(s) may also be mounted, utilizing die interconnects, to the bottom, outer metallization layer that includes metal interconnects between BGA interconnects.

### SUMMARY

Aspects disclosed in the detailed description include an integrated circuit (IC) package having a package interconnect including a pillar and a solder cap coupled to a bottom surface of the pillar to reduce the height of the IC package. The IC package includes a substrate comprising an outer metallization layer having a metal pad and a package mold layer adjacent to the outer metallization layer. The pillar has a top surface and a bottom surface. The pillar extends through the package mold layer with the top surface coupled to the metal pad and the bottom surface coupled to the solder cap. In contrast to conventional package interconnects, such as ball grid arrays (BGAs), for example, deploying the solder cap on the bottom surface of the pillar advantageously results in using less solder and a tighter pitch between adjacent package interconnects because the width of the pillar is less than a solder ball in a BGA. Additionally, in contrast to costly package interconnect processes, such as package interconnects utilizing an electroless nickel immersion gold (ENIG) metal plating process, deploying the solder cap on the bottom surface of the pillar advantageously utilizes conventional packaging to produce a highly reliable solder joint without utilizing additional ENIG processes.

In this regard in one aspect, an electronic device is disclosed. The electronic device comprises an integrated circuit (IC) package and a package interconnect. The IC package includes a substrate extending in a first direction which comprises an outer metallization layer having a metal pad and a package mold layer adjacent to the outer metallization layer. The package interconnect comprises a pillar extending in a second direction through the package mold layer. The pillar has a top surface and a bottom surface wherein the top surface coupled to the metal pad. The package interconnect also comprises a solder cap coupled to the bottom surface.

In another aspect, a method for fabricating an electronic device is disclosed. The method includes forming an integrated circuit (IC) package and forming a package interconnect. Forming the integrated circuit (IC) package includes forming a substrate extending in a first direction wherein the substrate comprises an outer metallization layer having a metal pad and forming a package mold layer adjacent to the outer metallization layer. Forming the package interconnect includes forming a pillar extending in a second direction through the package mold layer wherein the pillar has a top surface and a bottom surface. The top surface is coupled to the metal pad. Forming the package interconnect also includes forming a solder cap coupled to the bottom surface.

### BRIEF DESCRIPTION OF THE DRAWINGS

FIG. 1 is a side view of an exemplary three-dimensional (3D) integrated circuit (IC) (3DIC) package that includes a package interconnect including solder balls in a ball grid array (BGA);

FIG. 2 is a side view of an exemplary 3DIC package that includes a package interconnect including a pillar and a solder cap coupled to a bottom surface of the pillar to reduce the height of the 3DIC package;

FIG. 3 is a side view of an exemplary electronic device including the 3DIC package in FIG. 2 coupled to a printed circuit board (PCB);

FIG. 4 is a flowchart illustrating an exemplary fabrication process of fabricating an electronic device including an IC package such as the 3DIC package described in FIG. 2, wherein the IC package includes a package interconnect, the package interconnect, including, but not limited to, the package interconnect(s) in FIGS. 2 and 3;

FIGS. 5A-5E is a flowchart illustrating another exemplary fabrication process of fabricating a package interconnect such as the package interconnects in the 3DIC package described in FIGS. 2 and 3, wherein the package interconnect includes a pillar and a solder cap coupled to a bottom surface of the pillar to reduce the height of the 3DIC package, including, but not limited to, the package interconnect(s) in FIGS. 2 and 3;

FIGS. 6A-6M are exemplary fabrication stages during fabrication of the package interconnect according to the fabrication process in FIGS. 5A-5E;

FIG. 7 is a flowchart illustrating an exemplary assembly process of assembling an electronic device such as the electronic device having a 3DIC package coupled to a PCB in FIG. 2 and utilizing the 3DIC package fabricated according to the fabrication process in FIGS. 5A-5E, wherein the 3DIC package employs a package interconnect including a pillar and a solder cap coupled to a bottom surface of the pillar to reduce the height of the 3DIC package including, but not limited to, the package interconnect(s) in FIGS. 2 and 3;

FIGS. 8A-8B are exemplary assembly stages during assembly of the electronic device according to the assembly process in FIG. 7;

FIG. 9 is a block diagram of an exemplary processor-based system that can include components such as an electronic device, wherein the electronic device includes a 3DIC package fabricated according to the fabrication process in FIGS. 4 and 5A-5E, wherein the 3DIC package employs a package interconnect including a pillar and a solder cap coupled to a bottom surface of the pillar to reduce the height of the 3DIC package including, but not limited to, the package interconnect(s) in FIGS. 2 and 3; and

FIG. 10 is a block diagram of an exemplary wireless communications device that includes radio-frequency (RF) components formed from one or more electronic devices, wherein the electronic device includes a 3DIC package fabricated according to the fabrication process in FIGS. 4 and 5A-5E, wherein the 3DIC package employs a package interconnect including a pillar and a solder cap coupled to a bottom surface of the pillar to reduce the height of the 3DIC package including, but not limited to, the package interconnect(s) in FIGS. 2 and 3.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include an integrated circuit (IC) package having a package interconnect including a pillar and a solder cap coupled to a bottom surface of the pillar to reduce the height of the IC package. The IC package includes a substrate comprising an outer metallization layer having a metal pad and a package mold layer adjacent to the outer metallization layer. The pillar has a top surface and a bottom surface. The pillar extends through the package mold layer with the top surface coupled to the metal pad and the bottom surface coupled to the solder cap. In contrast to conventional package interconnects, such as ball grid arrays (BGAs), for example, deploying the solder cap on the bottom surface of the pillar advantageously results in using less solder and a tighter pitch between adjacent package interconnects because the width of the pillar is less than a solder ball in a BGA. Additionally, in contrast to costly package interconnect processes, such as package interconnects utilizing an electroless nickel immersion gold (ENIG) metal plating process, deploying the solder cap on the bottom surface of the pillar advantageously utilizes conventional packaging to produce a highly reliable solder joint without utilizing additional ENIG processes.

Before discussing exemplary aspects starting at FIG. 2, a three-dimensional (3D) IC (3DIC) package utilizing conventional solder balls in a BGA as a package interconnect where the height of the solder balls limits the overall height of the 3DIC package is first discussed.

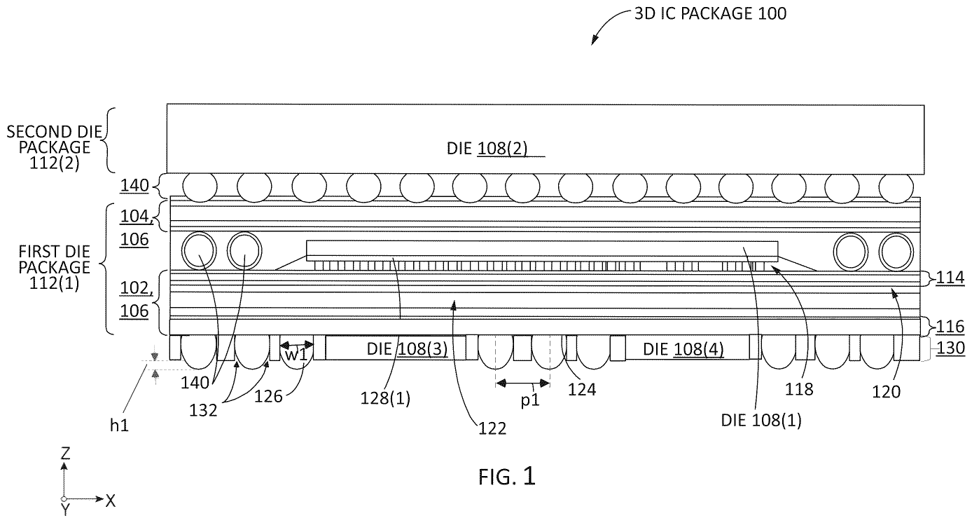

In this regard, FIG. 1 is a side view of an IC package 100, which in this example is a 3DIC package 100. The IC package 100 includes a package substrate 102 and an interposer substrate 104. The package substrate 102 and the interposer substrate 104 commonly route signals and power and, for convenience, may both be referred to simply as a substrate 106.

In this example, the 3DIC package 100 includes first and second dies 108(1), 108(2) that are included in respective first and second die packages 112(1), 112(2) that are stacked on top of each other in the vertical direction (Z-axis direction). The first die package 112(1) of the IC package 100 includes the first die 108(1) coupled to the package substrate 102. In this example, the package substrate 102 includes a first, upper metallization layer 114. The first, upper metallization layer 114 provides an electrical interface for signal routing to the first die 108(1). The first die 108(1) is coupled to die interconnects 118 (e.g., raised metal bumps, pillars) that are electrically coupled to metal interconnects 120 in the first, upper metallization layer 114. The metal interconnects 120 in the first, upper metallization layer 114 are coupled to metal vias 122 (not visible) in the package substrate 102, which are coupled to metal interconnects 124 in a second, bottom metallization layer 116. In this manner, the package substrate 102 provides interconnections between its first and second metallization layers 114 and 116 to provide signal routing to the first die 108(1). Solder balls 126 (e.g., ball grid array (BGA) interconnects) are coupled to the metal interconnects 124 in the second, bottom metallization layer 116 to provide interconnections through the package substrate 102 to the first die 108(1) through the die interconnects 118. In this example, a first, active side 128(1) of the first die 108(1) is adjacent to and coupled to the package substrate 102, and more specifically the first, upper metallization layer 114 of the package substrate 102.

A third die 108(3) and fourth die 108 (4) are attached to the bottom side of the first die package 112(1). The third die 108(3) and the fourth die 108(4) can be any silicon or gallium arsenide electrical device which has a back side that may be grindable. Typical widths in the z-direction of the third die 108(3) and the fourth die 108(4) are on the order of 100 microns. The third die 108(3) and the fourth die 108(4) include die connects (not shown) which couple to the metal interconnects 124 in the second, bottom metallization layer 116 and through metal pads (not shown). The solder balls 126 extend beyond a solder mask layer 130 by a height, h1, which is about 50 micrometers (μm). Additionally, since the solder balls 126 are large and extend in the Z-axis direction to the second, bottom metallization layer 116, laser ablations 132 are necessary to provide access for the energy from the bottom side of the solder balls 126 to reflow the ball when coupling to a printed circuit board (PCB) (not shown). Moreover, due to the width, w1, of the solder balls 126 being around 240 μm, the pitch, p1, the distance between the center of adjacent solder balls 126 is limited to no smaller than around 350 μm.

FIG. 2 is a side view of an exemplary 3DIC package 200 that includes a package interconnect 202 including a pillar 204 and a solder cap 206 coupled to a bottom surface of the pillar 204 to reduce the height of the 3DIC package 200. The solder cap 206 may be composed of a tin (Sn) or a tin silver (SnAg) compound. The 3DIC package 200 includes a substrate 208 extending in a first, horizontal direction (X-, Y-axes direction). The substrate 208 includes metallization layers 210A-210F including an upper, outer metallization layer 210A and a lower, outer metallization layer 210F. The lower, outer metallization layer 210F includes a metal pad 212. The 3DIC package 200 also includes a package mold layer 214 adjacent to the lower, outer metallization layer 210F.

The package interconnect 202 extends in a second, vertical direction (Z-axis direction) through the package mold layer 214. The pillar 204 has a top surface 216 and a bottom surface 218. The top surface 216 is coupled to the metal pad 212. The bottom surface 218 of the pillar 204 is coupled to the solder cap 206. The pillar 204 is a metal and preferably composed of copper (Cu).

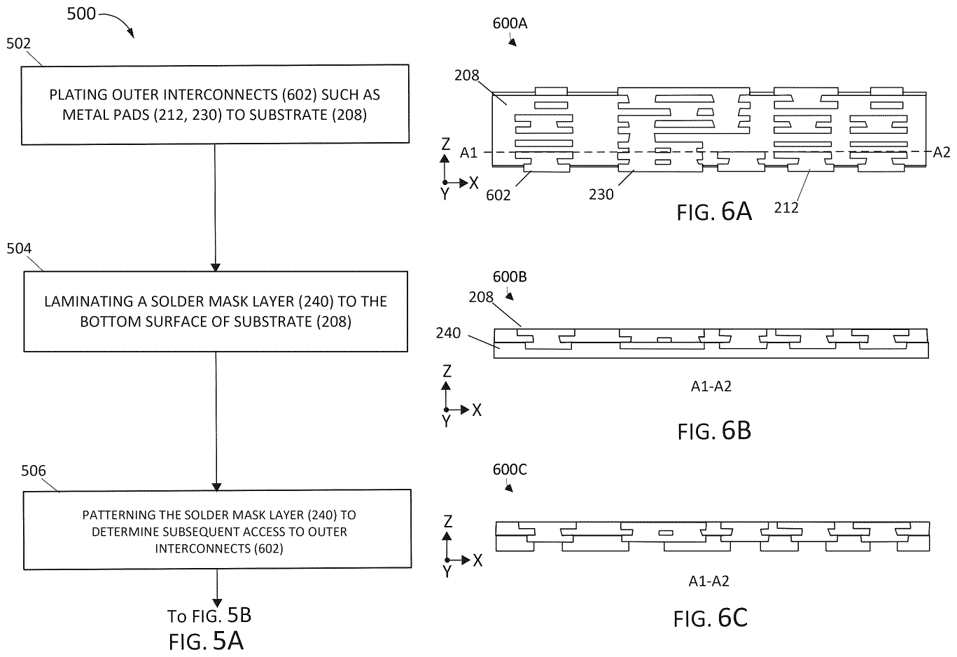

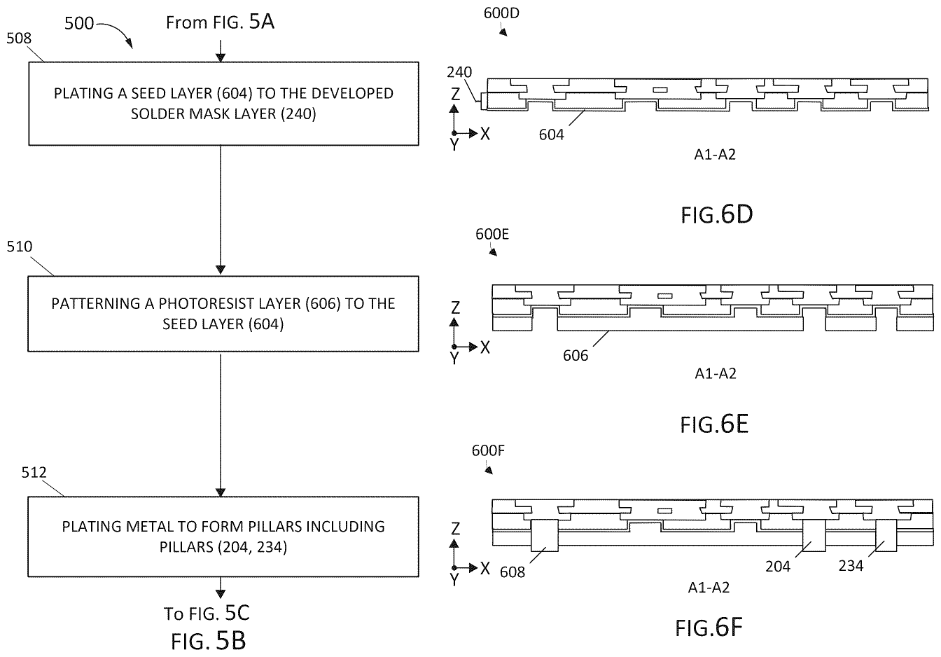

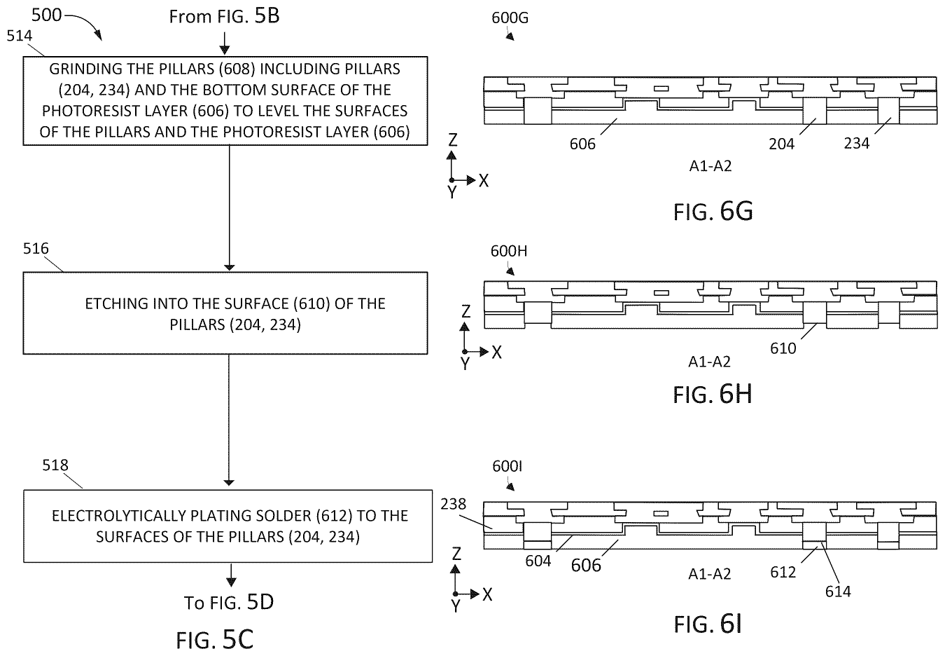

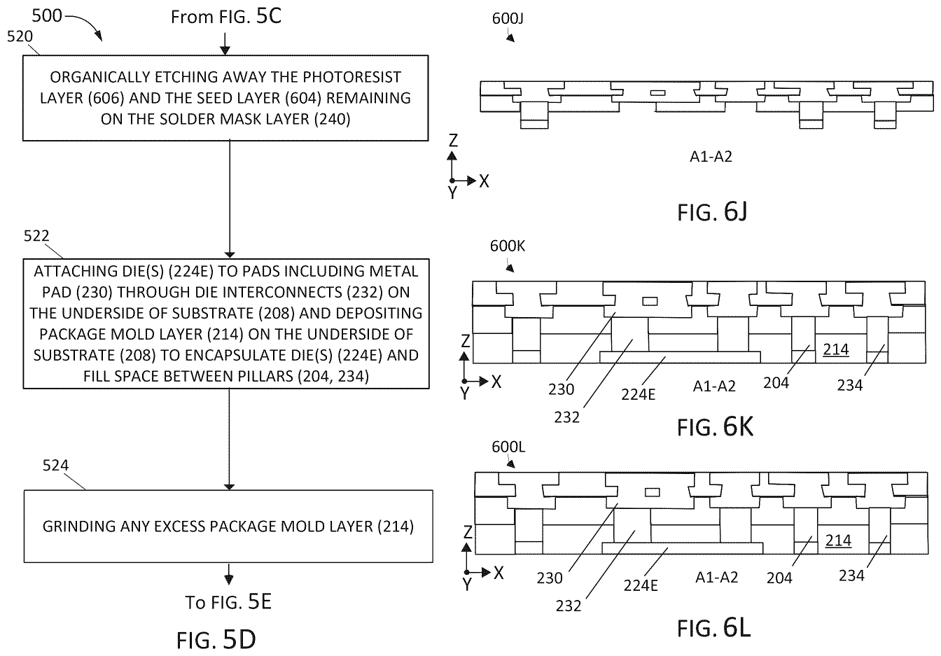

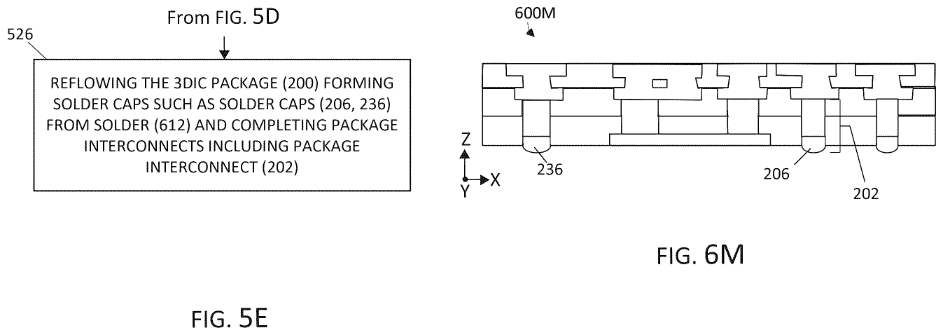

The package interconnect 202 has a sidewall 222 defined between the pillar 204 and the package mold layer 214. During manufacturing of the package interconnect 202 which will be discussed in FIGS. 5A-5E and 6A-6M, a photoresist layer (not shown) surrounds the pillar 204 and is etched away to access the surface of pillar 204. Diffusion of the pillar 204 is limited to the surface with the solder cap 206. As such, the sidewall 222 does not comprise a diffusion barrier.

The 3DIC package 200 also includes dies 224(A)-224(E) where dies 224(A)-224(D) are electrically coupled to the top side of the substrate 208 through metal pads 226 and die interconnects 228. Die 224(F) is electrically coupled to the bottom side of the substrate 208 through metal pads 230 and die interconnects 232.

The pillar 204 has a width, w2, around 170 μm, allowing the pitch, p2, as defined between the center of the pillar 204 and an adjacent pillar, such as pillar 234, to be between 250-280 μm. The lower end of the pitch is constrained by minimum manufacturing limits between adjacent pillars when applying the package mold layer 214. Solder cap 236, like the solder cap 206, extends beyond a bottom surface 238 of the package mold layer 214 by a height h2. The height h2 is less than or equal to 10 μm which reduces the height in the vertical direction (Z-axis direction) of the overall 3DIC package 200.

The substrate 208 also includes a solder mask layer 240 between the outer metallization layer 210F and the package mold layer 214. The width, w2, of the pillar 204 is the same through both the package mold layer 214 and the solder mask layer 240.

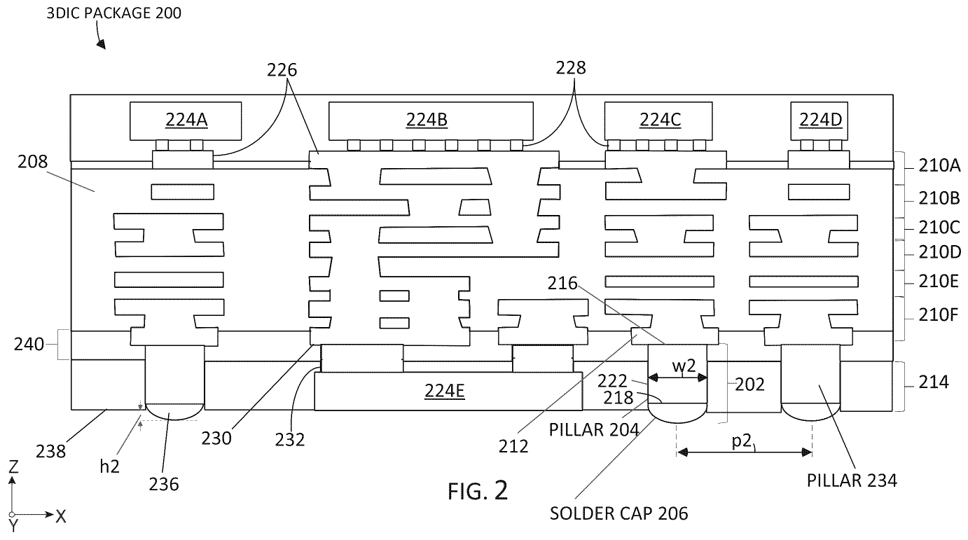

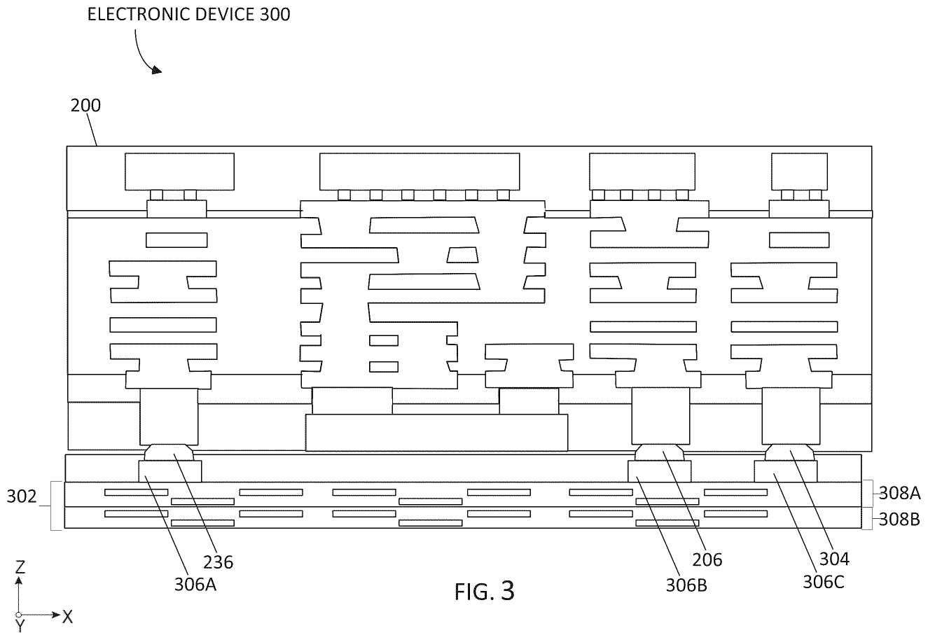

FIG. 3 is a side view of an exemplary electronic device 300 including the exemplary 3DIC package 200 in FIG. 2 coupled to a PCB 302 through solder caps 206, 236, and 304. The PCB 302 includes metal pads 306A-306C to couple to the solder caps 236, 206, and 304, respectively. The PCB 302 is suited to electrically couple the electronic device 300 to other electronic devices and/or dies (not shown) through the metal pads 306A-306C and metallization layers 308A-308B.

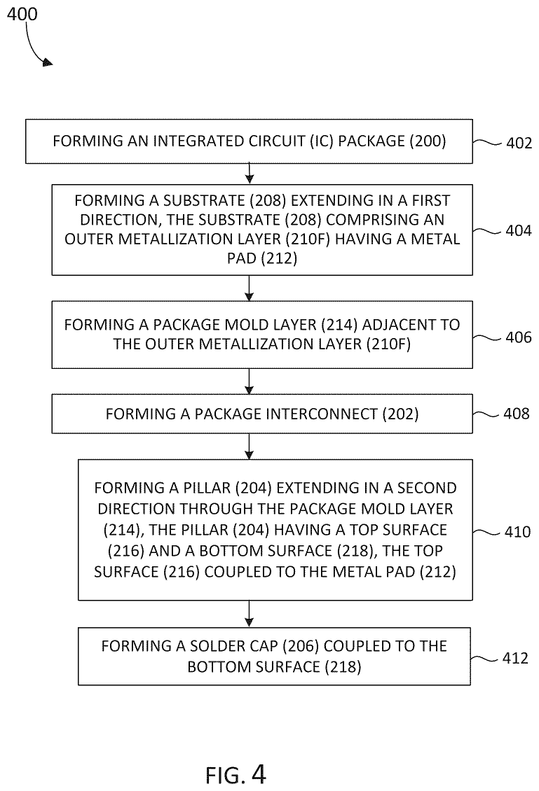

An electronic device including an IC package, such as the 3DIC package 200, which includes a package interconnect including a pillar and a solder cap coupled to a bottom surface of the pillar to reduce the height of the IC package including, but not limited to, the package interconnects in FIGS. 2 and 3 can be fabricated by different fabrication processes. FIG. 4 is a flowchart illustrating an exemplary fabrication process of fabricating an electronic device including an IC package such as the 3DIC package described in FIG. 2, wherein the IC package includes a package interconnect, the package interconnect, including, but not limited to, the package interconnect(s) in FIGS. 2 and 3.

In this regard, a first exemplary step in the fabrication process 400 of FIG. 4 can include forming an IC package 200 (block 402 in FIG. 4). Forming the IC package 200 of the fabrication process 400 can include forming a substrate 208 extending in a first direction, the substrate 208 comprising an outer metallization layer 210F having a metal pad 212 (block 404 in FIG. 4). A next step in forming the IC package 200 of the fabrication process 400 can include forming a package mold layer 214 adjacent to the outer metallization layer 210F (block 406 in FIG. 4). A next step in forming the IC package 200 of the fabrication process 400 can include forming a package interconnect 202 (block 408 in FIG. 4). Forming the package interconnect 202 of the fabrication process 400 can include forming a pillar 204 extending in a second direction through the package mold layer 214, the pillar 204 having a top surface 216 and a bottom surface 218, the top surface 216 coupled to the metal pad 212 (block 410 in FIG. 4). Forming the package interconnect 202 of the fabrication process 400 can also include forming a solder cap 206 coupled to the bottom surface 218 (block 412 in FIG. 4).

Other fabrication processes can also be employed to fabricate an electronic device including an IC package such as the 3DIC package described in FIGS. 2 and 3, wherein the 3DIC package includes a package interconnect, the package interconnect, including, but not limited to, the package interconnect(s) in FIGS. 2 and 3. In this regard, FIGS. 5A-5E is a flowchart illustrating another exemplary fabrication process of fabricating a package interconnect such as the package interconnects in the 3DIC package described in FIGS. 2 and 3, wherein the package interconnect includes a pillar and a solder cap coupled to a bottom surface of the pillar to reduce the height of the 3DIC package, including, but not limited to, the package interconnect(s) in FIGS. 2 and 3. FIGS. 6A-6M are exemplary fabrication stages during fabrication of the package interconnect according to the fabrication process in FIGS. 5A-5E.

In this regard, as shown in fabrication stage 600A in FIG. 6A, an exemplary step in the fabrication process 500 is plating outer interconnects 602 such as the metal pads 212, 230 to the substrate 208 (block 502 in FIG. 5A). The plating process in block 502 may include depositing a Cu seed layer, applying a photo resist layer, exposing the photo resist layer to form an outline for the outer interconnects 602, plating metal (e.g., Cu) to form the outer interconnects 602 including the metal pads 212, 230, and etching the remaining Cu seed layer. For simplicity, the fabrication process 500 will be described beginning at stage 600B from cut lines A1-A2 in FIG. 6A descending in the negative Z-axis direction in stage 600A. As shown at fabrication stage 600B in FIG. 6B, a next step in the fabrication process 500 can include laminating a solder mask layer 240 to the bottom surface of the substrate 208 (block 504 in FIG. 5A). As shown at fabrication stage 600C in FIG. 6C, a next step in the fabrication process 500 can include patterning the solder mask layer 240 to determine subsequent access to the outer interconnects 602 (block 506 in FIG. 5A). The patterning process in block 506 may include exposing the solder mask layer 240 to ultraviolet rays through a mask, developing the remaining solder mask layer 240, and desmearing the surfaces of the solder mask layer 240 and the outer interconnects 602 to roughen the respective surfaces for subsequent plating of a seed layer. As shown at fabrication stage 600D in FIG. 6D, a next step in the fabrication process 500 can include plating a seed layer 604 (e.g., Cu) to the developed solder mask layer 240 (block 508 in FIG. 5B). As shown at fabrication stage 600E in FIG. 6E, a next step in the fabrication process 500 can include patterning a photoresist layer 606 to the seed layer 604 (block 510 in FIG. 5B). The patterning process in block 510 may include laminating the photoresist layer 606 to the seed layer 604, exposing the photoresist layer 606 with ultraviolet rays through a mask, and developing the remaining photoresist layer 606. As shown at fabrication stage 600F in FIG. 6F, a next step in the fabrication process 500 can include plating metal (e.g., Cu) to form pillars 608 including the pillars 204, 234 (block 512 in FIG. 5B).

As shown at fabrication stage 600G in FIG. 6G, a next step in the fabrication process 500 can include grinding the pillars 608 including the pillars 204, 234 and the bottom surface of the photoresist layer 606 to level the surfaces of the pillars 608 and the photoresist layer 606 (block 514 in FIG. 5C). As shown at fabrication stage 600H in FIG. 6H, a next step in the fabrication process 500 can include etching approximately 10 μm into a surface 610 of the pillars 204, 234 (block 516 in FIG. 5C). As shown at fabrication stage 600I in FIG. 6I, a next step in the fabrication process 500 can include electrolytically plating solder 612 to the surfaces of the pillars 204, 234 (block 518 in FIG. 5C). The plating process in block 518 includes depositing a barrier layer 614 on the surfaces 610 of the pillars to prevent diffusion of the pillars.

As shown at fabrication stage 600J in FIG. 6J, a next step in the fabrication process 500 can include organically etching away the photoresist layer 606 and the seed layer 604 remaining on the solder mask layer 240 (block 520 in FIG. 5D). As shown at fabrication stage 600K in FIG. 6K, a next step in the fabrication process 500 can include attaching a die(s) 224E to pads including the metal pad 230 through die interconnects 232 on the underside of the substrate 208 and depositing the package mold layer 214 on the underside of the substrate 208 to encapsulate the die(s) 224E and fill space between the pillars 204, 234 (block 522 in FIG. 5D). As shown at fabrication stage 600L in FIG. 6L, a next step in the fabrication process 500 can include grinding any excess package mold layer 214 (block 524 in FIG. 5D). As shown at fabrication stage 600M in FIG. 6M, a next step in the fabrication process 500 can include reflowing (also known as re-balling) the 3DIC package 200 forming solder caps such as the solder caps 206, 236 from the solder 612 and completing package interconnects including the package interconnect 202 (block 526 in FIG. 5E).

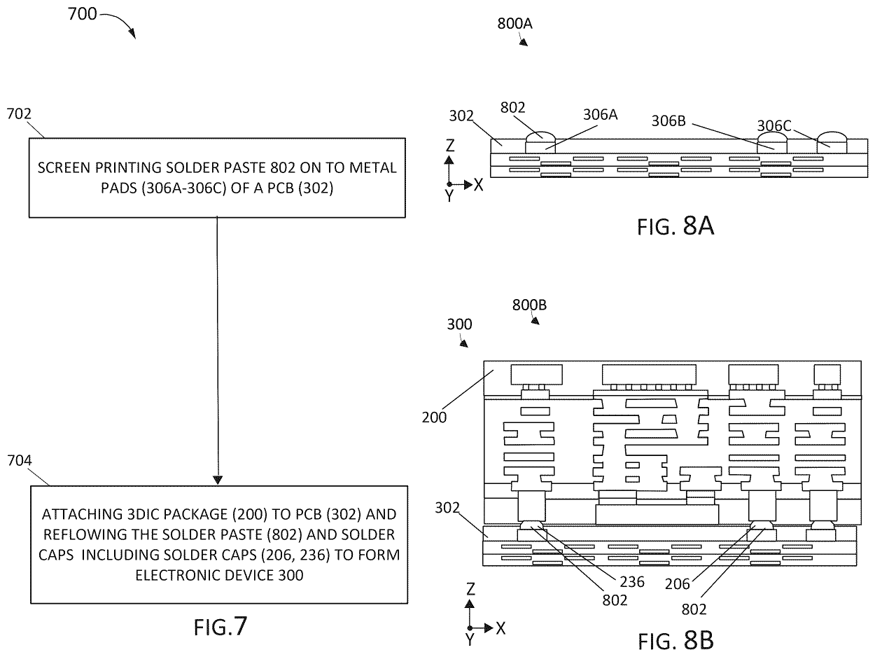

FIG. 7 is a flowchart illustrating an exemplary assembly process 700 of assembling an electronic device such as the electronic device 300 having a 3DIC package, such as the 3DIC package 200, coupled to a PCB in FIG. 2 and utilizing the 3DIC package fabricated according to the fabrication process 500 in FIGS. 5A-5E, wherein the 3DIC package employs a package interconnect including a pillar and a solder cap coupled to a bottom surface of the pillar to reduce the height of the 3DIC package including, but not limited to, the package interconnect(s) in FIGS. 2 and 3. FIGS. 8A-8B are exemplary assembly stages during assembly of the electronic device according to the assembly process 700 in FIG. 7.

In this regard, as shown in assembly stage 800A in FIG. 8A, an exemplary step in the assembly process 700 is screen printing solder paste 802 on to metal pads 306A-306C of a PCB 302 (block 702 in FIG. 7). As shown at assembly stage 800B in FIG. 8B, a next step in the assembly process 700 can include attaching the 3DIC package 200 to the PCB 302 and reflowing the solder paste 802 and solder caps including the solder caps 206, 236 to form the electronic device 300 (block 704 in FIG. 7).

Electronic devices that include an IC package, wherein the 3DIC package fabricated according to the fabrication process in FIGS. 5A-5E, wherein the 3DIC package employs a package interconnect including a pillar and a solder cap coupled to a bottom surface of the pillar to reduce the height of the 3DIC package, including, but not limited to, the package interconnects in FIGS. 2 and 3 and according to the exemplary processes in FIGS. 4 and 5A-5E, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

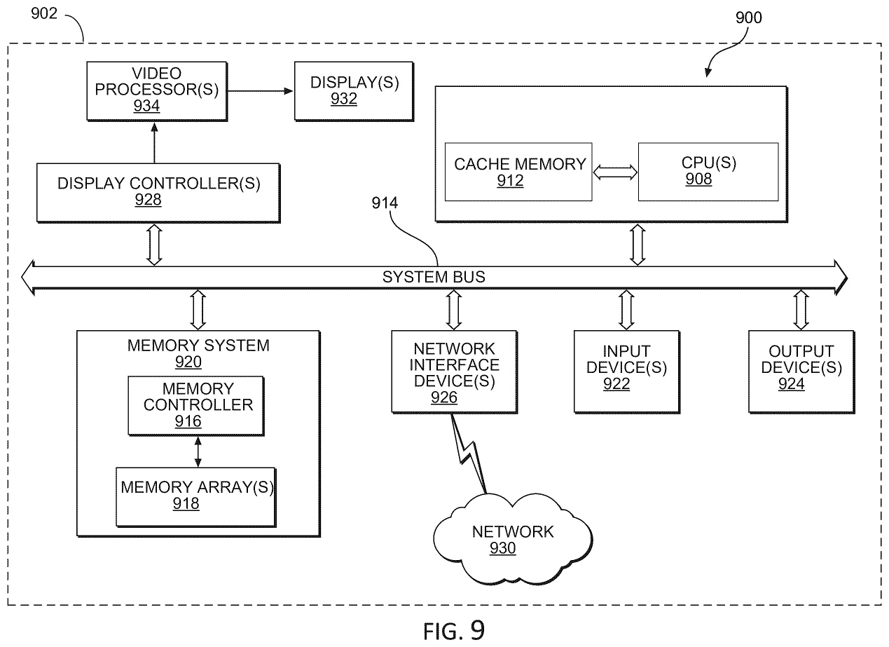

In this regard, FIG. 9 is a block diagram of an exemplary processor-based system that can include components such as an electronic device, wherein the electronic device includes a 3DIC package(s) fabricated according to the fabrication process in FIGS. 4 and 5A-5E, wherein the 3DIC package employs a package interconnect including a pillar and a solder cap coupled to a bottom surface of the pillar to reduce the height of the 3DIC package including, but not limited to, the package interconnect(s) in FIGS. 2 and 3, and according to any exemplary aspects disclosed herein. In this example, the processor-based system 900 may be assembled into one electronic device and a 3DIC package(s) 902 such as the IC package 200 in FIG. 2 utilizing the substrate 208. The processor-based system 900 includes a central processing unit (CPU) 908 that includes one or more processors 910, which may also be referred to as CPU cores or processor cores. The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. Each of the memory system(s) 920, the one or more input devices 922, the one or more output devices 924, the one or more network interface devices 926, and the one or more display controllers 928 can be provided in the same or different electronic devices. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processor(s) 934, which process the information to be displayed into a format suitable for the display(s) 932. The display controller(s) 928 and video processor(s) 934 can be included as ICs in the same or different electronic devices, and in the same or different electronic devices containing the CPU 908, as an example. The display(s) 932 can include any type of display, including, but not limited to, a cathode ray tube (CRT), a liquid crystal display (LCD), a plasma display, a light emitting diode (LED) display, etc.

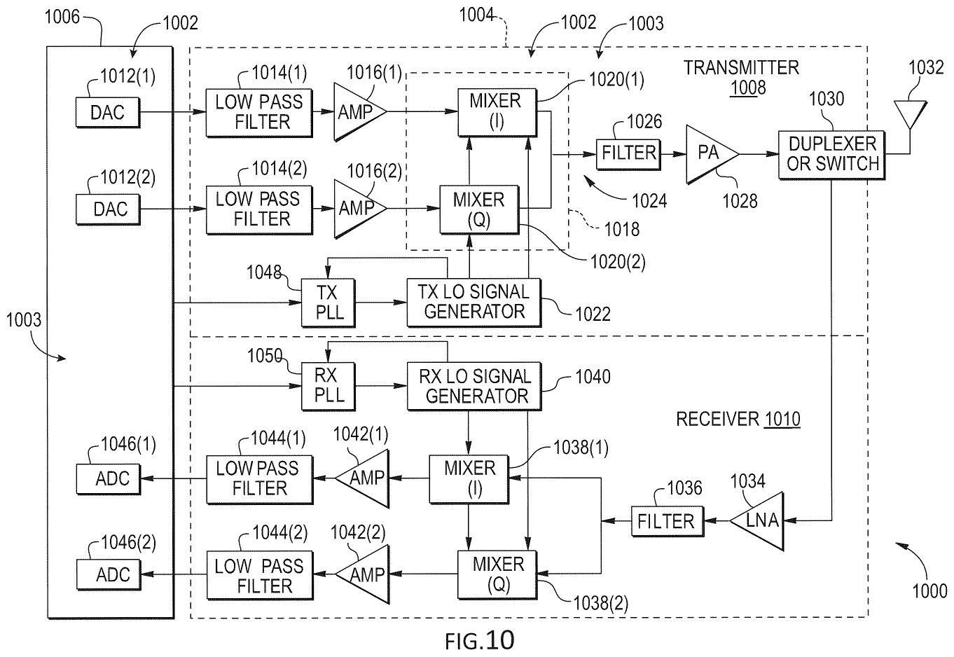

FIG. 10 is a block diagram of an exemplary wireless communications device 1000 that includes radio-frequency (RF) components formed from one or more electronic devices, wherein the electronic device includes a 3DIC package 1002 fabricated according to the fabrication process in FIGS. 4 and 5A-5E, wherein the 3DIC package 1002 employs a package interconnect including a pillar and a solder cap coupled to a bottom surface of the pillar to reduce the height of the 3DIC package including, but not limited to, the package interconnect(s) in FIGS. 2 and 3, and according to any exemplary aspects disclosed herein. The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals (e.g., I and Q output currents) for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An electronic device, comprising:
an integrated circuit (IC) package, comprising:
   a substrate extending in a first direction, the substrate comprising an outer metallization layer having a metal pad;
   a package mold layer adjacent to the outer metallization layer;
   a package interconnect, comprising:
      a pillar extending in a second direction through the package mold layer, the pillar having a top surface and a bottom surface, the top surface coupled to the metal pad; and
      a solder cap coupled to the bottom surface.
2. The electronic device of clause 1, wherein the package interconnect has a sidewall not comprising a diffusion barrier.
3. The electronic device of clause 1 or 2, wherein the package mold layer has a second bottom surface, wherein the solder cap extends beyond the second bottom surface by less than or equal to 10 micrometers (μm).
4. The electronic device of any of clauses 1-3, further comprising:
a second pillar adjacent to the pillar, wherein a pitch between the second pillar and the pillar is less than or equal to 280 micrometers (μm).
5. The electronic device of any of clauses 1-4, further comprising:
a printed circuit board coupled to the solder cap.
6. The electronic device of any of clauses 1-5, further comprising:
a solder mask layer between the package mold layer and the outer metallization layer, the pillar extending through the solder mask layer and the package mold layer, the pillar having a width which is the same through both the package mold layer and the solder mask layer.
7. The electronic device of any of clauses 1-6, wherein the width of the pillar is around 150 μm.
8. The electronic device of any of clauses 1-7 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.
9. A method of fabricating an electronic device, comprising:
forming an integrated circuit (IC) package, comprising:
   forming a substrate extending in a first direction, the substrate comprising an outer metallization layer having a metal pad;
   forming a package mold layer adjacent to the outer metallization layer; and forming a package interconnect, comprising:
forming a pillar extending in a second direction through the package mold layer, the pillar having a top surface and a bottom surface, the top surface coupled to the metal pad; and
   forming a solder cap coupled to the bottom surface.
10. The method of clause 9, wherein the package interconnect has a sidewall not comprising a diffusion barrier.
11. The method of clause 9 or 10, wherein the package mold layer has a second bottom surface, wherein the solder cap extends beyond the second bottom surface by less than or equal to 10 micrometers (μm).
12. The method of any of clauses 9-11, further comprising:
forming a second pillar adjacent to the pillar, wherein a pitch between the second pillar and the pillar is less than or equal to 280 nanometers (nm).
13. The method of any of clauses 9-12, further comprising:
forming a printed circuit board coupled to the solder cap.
14. The method of any of clauses 9-13, further comprising:
forming a solder mask layer between the package mold layer and the outer metallization layer, the pillar extending through the solder mask layer and the package mold layer, the pillar having a width which is the same through both the package mold layer and the solder mask layer.
15. The method of any of clauses 9-14, wherein the width of the pillar is 150 μm.
16. The method of any of clauses 9-15, wherein forming the solder cap coupled to the bottom surface comprises:
etching into the bottom surface; and
electrolytically plating solder to the bottom surface.
17. The method of clause 16, wherein forming the solder cap coupled to the bottom surface further comprises:
reflowing solder to form the solder cap.

What is claimed is:

1. An electronic device, comprising:
an integrated circuit (IC) package, comprising:
a substrate extending in a first direction, the substrate comprising an outer metallization layer having a metal pad;
a package mold layer adjacent to the outer metallization layer;
a package interconnect, comprising:
a pillar extending in a second direction through the package mold layer, the pillar having a top surface and a bottom surface, the top surface coupled to the metal pad; and
a solder cap coupled to the bottom surface.

2. The electronic device of claim 1, wherein the package interconnect has a sidewall not comprising a diffusion barrier.

3. The electronic device of claim 1, wherein the package mold layer has a second bottom surface, wherein the solder cap extends beyond the second bottom surface by less than or equal to 10 micrometers (μm).

4. The electronic device of claim 1, further comprising:
a second pillar adjacent to the pillar, wherein a pitch between the second pillar and the pillar is less than or equal to 280 micrometers (μm).

5. The electronic device of claim 1, further comprising:
a printed circuit board coupled to the solder cap.

6. The electronic device of claim 1, further comprising:
a solder mask layer between the package mold layer and the outer metallization layer, the pillar extending through the solder mask layer and the package mold layer, the pillar having a width which is the same through both the package mold layer and the solder mask layer.

7. The electronic device of claim 6, wherein the width of the pillar is around 150 μm.

8. The electronic device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

9. A method of fabricating an electronic device, comprising:
forming an integrated circuit (IC) package, comprising:
forming a substrate extending in a first direction, the substrate comprising an outer metallization layer having a metal pad;
forming a package mold layer adjacent to the outer metallization layer; and
forming a package interconnect, comprising:
forming a pillar extending in a second direction through the package mold layer, the pillar having a top surface and a bottom surface, the top surface coupled to the metal pad; and
forming a solder cap coupled to the bottom surface.

10. The method of claim 9, wherein the package interconnect has a sidewall not comprising a diffusion barrier.

11. The method of claim 9, wherein the package mold layer has a second bottom surface, wherein the solder cap extends beyond the second bottom surface by less than or equal to 10 micrometers (μm).

12. The method of claim 9, further comprising:
forming a second pillar adjacent to the pillar, wherein a pitch between the second pillar and the pillar is less than or equal to 280 nanometers (nm).

13. The method of claim 9, further comprising:
forming a printed circuit board coupled to the solder cap.

14. The method of claim 9, further comprising:
forming a solder mask layer between the package mold layer and the outer metallization layer, the pillar extending through the solder mask layer and the package mold layer, the pillar having a width which is the same through both the package mold layer and the solder mask layer.

15. The method of claim 14, wherein the width of the pillar is 150 μm.

16. The method of claim 9, wherein forming the solder cap coupled to the bottom surface comprises:
etching into the bottom surface; and
electrolytically plating solder to the bottom surface.

17. The method of claim 16, wherein forming the solder cap coupled to the bottom surface further comprises:
reflowing solder to form the solder cap.
